(19) United States
(12) Patent Application Publication
(10) Pub. No.: US 2004/0175918 A1
(43) Pub. Date: Sep. 9, 2004

(54) Novel formation of an aluminum contact pad free of plasma induced damage by applying CMP

(75) Inventors: Pao-Kang Niu, Hsinchu (TW); Shui-Hung Chen, Hsin-Chu (TW); Mu-Chi Chiang, Hsinchu (TW); Jou-Yin Liu, Taipei (TW); Harry Chuang, Austin, TX (US)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/379,818

(22) Filed: Mar. 5, 2003

(51) Int. Cl. H01L 21/4763

(52) U.S. Cl. 438/618

(57) ABSTRACT

A new method is provided for the creation of an aluminum contact pad. A layer of passivation is created over the surface of a substrate, an opening is created through the layer of passivation. A layer of aluminum is deposited over the surface of the deposited layer of passivation, filling the opening that has been created there-through. The deposited layer of aluminum is then polished down to the surface of the layer of passivation, leaving the deposited aluminum in place inside the opening created through the layer of passivation for purposes of serving as a contact pad.

### BACKGROUND OF THE INVENTION

(1) Field of the Invention

The invention relates to the fabrication of integrated circuit devices, and more particularly, to creating a contact pad that is free of plasma induced surface damage. Methods of Chemical Mechanical Polishing are part of the process.

(2) Description of the Prior Art

In the design and manufacturing of semiconductor devices, Very Large Scale Integration (VSLI) and Ultra Large-Scale Integration (ULSI) technologies are used for the creation of complex semiconductor devices in or over the surface of a silicon substrate. Improved device performance is typically achieved by reducing device dimensions, present day technology is reaching device dimensions in the deep sub-micron range down to 0.1 μm. To create device features that are part of semiconductor devices, the technique of photolithography is frequently applied. Using this technology device features or device patterns are transferred from a (relatively large dimensional) reticle or photomask to a target surface that is typically the surface of a semiconductor substrate. Step-and-repeat processes allow for the step-wise or gradual transfer of a relatively large dimensional image to ever smaller reproductions of this image to the point where the desired, if needed sub-micron, dimensions of the semiconductor device are reached.

The creation of monolithic semiconductor devices implies the creation of numerous interacting electrical device elements created in or over the surface of a silicon semiconductor substrate. Among these device elements are for instance transistors, diodes, bipolar transistors, CMOS Field Effect Transistors of either N or P channel type and the like. After semiconductor devices and device elements have been created, these devices and device elements must be interconnected for the formation of functional semiconductor devices. In addition, the interconnected devices and device elements may be further interconnected to device supporting interfaces such as semiconductor substrates, printed circuit boards, flex circuits or a metallized or glass substrates or semiconductor device mounting supports.

Bond pads, which are frequently used for interconnecting devices and device elements, present a continuing challenge in the creation of semiconductor devices of sub-micron device dimensions. Continued effort is thereby dedicated to creating bond pads that are simple, reliable and inexpensive.

Bond pads are generally used for wiring the die to components that are external to the die, such as a bond wire that is attached to a bond pad of a semiconductor die at one end and to an exposed surface of a Printed Circuit Board (PCB) at the other end of the wire. Constant effort is dedicated in the art of creating semiconductor devices to achieve improvements in the creation of bond pads, improvements that are aimed at simplifying the manufacturing process and further at enhancing bond pad reliability.

Materials that are typically used for bond pads include metallic materials, such as tungsten and aluminum, while heavily doped polysilicon can also be used for contacting material. The bond pad is formed on the top surface of the semiconductor device whereby the electrically conducting material is frequently embedded in an insulating layer of dielectric. In using polysilicon as the bond pad material, polysilicon can be doped with an n-type dopant for contacting N-regions while it can be doped with p-type dopant for contacting P-regions. This approach of doping avoids inter-diffusion of the dopants and dopant migration. It is clear that low contact resistance for the bond pad area is required while concerns of avoidance of moisture or chemical solvent absorption, thin film adhesion characteristics, delamination and cracking play an important part in the creation of bond pads.

U.S. Pat. No. 6,350,680 B1 (Shih et al.) claims an aluminum CMP step.

U.S. Pat. No. 6,123,992 (Sugai) claims an aluminum CMP of an aluminum Metal layer. This patent comprises incompletely filling a hole with aluminum, assuring that the surface of the deposited aluminum is free of oxide and then carrying out a heat treatment, causing a reflow of the aluminum based layer.

U.S. Pat. No. 5,700,383 (Feller et al.) shows a CMP method and slurry for an aluminum CMP process. This patent provides for slurries and methods of CMP of an aluminum and titanium aluminide surface.

U.S. Pat. No. 5,607,718 (Sasaki et al.) shows another CMP method and slurry for an aluminum CMP process, this patent provides a polishing apparatus.

U.S. Pat. No. 5,470,788 (Biery et al.) shows another CMP method and slurry for an aluminum CMP process. This patent provides a method of making a self-aligned, lateral diffusion barrier in metal lines in order to eliminate electromigration.

### SUMMARY OF THE INVENTION

A principle objective of the invention is to provide a method of creating an aluminum bond pad whereby damage to the surface of the aluminum caused by exposure to plasma etching is avoided.

Another objective of the invention is to provide a method of creating an aluminum contact pad that allows for optimization of surface polishing of the created aluminum bond pad by optimizing parameters of CMP surface polishing.

In accordance with the objectives of the invention a new method is provided for the creation of an aluminum contact pad. A layer of passivation is created over the surface of a substrate, an opening is created through the layer of passivation. A layer of aluminum is deposited over the surface of the deposited layer of passivation, filling the opening that has been created there through. The deposited layer of aluminum is then polished down to the surface of the layer of passivation, leaving the deposited aluminum in place inside the opening created through the layer of passivation for purposes of serving as a contact pad.

### BRIEF DESCRIPTION OF THE DRAWINGS

FIGS. 1 through 6 show a prior art method of creating a bond pad, as follows:

FIG. 1 shows a cross section of a substrate, a patterned first layer of dielectric has been created over the surface of the substrate, a layer of aluminum has been deposited.

FIG. 2 shows a cross section after the creation of a first photoresist mask.

FIG. 3 shows a cross section after the deposited layer of aluminum has been etched in accordance with the first photoresist mask.

FIG. 4 shows a cross section after a second layer of dielectric has been deposited.

FIG. 5 shows a cross section after a second photoresist mask has been created.

FIG. 6 shows a cross section after the second layer of dielectric has been etched in accordance with the second photoresist mask.

FIGS. 7 through 9 show the invention, as follows:

FIG. 7 shows a cross section of a substrate, a patterned first layer of dielectric has been created over the surface of the substrate, a layer of aluminum has been deposited.

FIG. 8 shows a cross section during the process of polishing the surface of the deposited layer of aluminum.

FIG. 9 shows a cross section after the layer of aluminum has been polished down to the surface of the layer of dielectric.

### DESCRIPTION OF THE PREFERRED EMBODIMENTS

A bond pad typically consists of an exposed aluminum pad to the surface of which a gold bond wire can be bonded. The conventional method for the creation of a contact pad is first briefly highlighted using FIGS. 1 through 6 for this purpose.

Shown in FIG. 1 is a cross section of a semiconductor substrate 10 in or over the surface of which a point 12 of top metal has been provided. Top metal 12 is in electrical contact with semiconductor devices created in or over the surface of substrate 10. The to be created contact pad must be aligned with top metal 12 in order to establish electrical contact with the semiconductor devices (not shown) that have been created in or over the surface of substrate 10.

A layer 14 of passivation has been deposited over the surface of substrate 10, this layer 14 of passivation may be a composite layer of passivation further interspersed with layers of etch stop material (not shown in FIG. 1). Additional layers of passivation (not shown) may be desired for additional protection of the surface of substrate 10, etch stop layers are provided for the conventional purpose of stopping an etch for (for instance) the creation of opening 13 through the layer 14 of passivation.

After opening 13 has been created through layer 14, a layer 16 of aluminum, comprising therein aluminum alloys, is deposited over the surface of passivation layer 14, filling opening 13 that has been created through the layer 14 of passivation. The creation of aluminum layer 16 applies conventional methods of metal rf sputtering, at a temperature between about 400 degrees C., using as source aluminum-copper material at a flow rate of between about 10 and 400 sccm and a pressure between about 1 and 100 mTorr, deposited to a thickness between about 4,000 and 11,000 Angstrom.

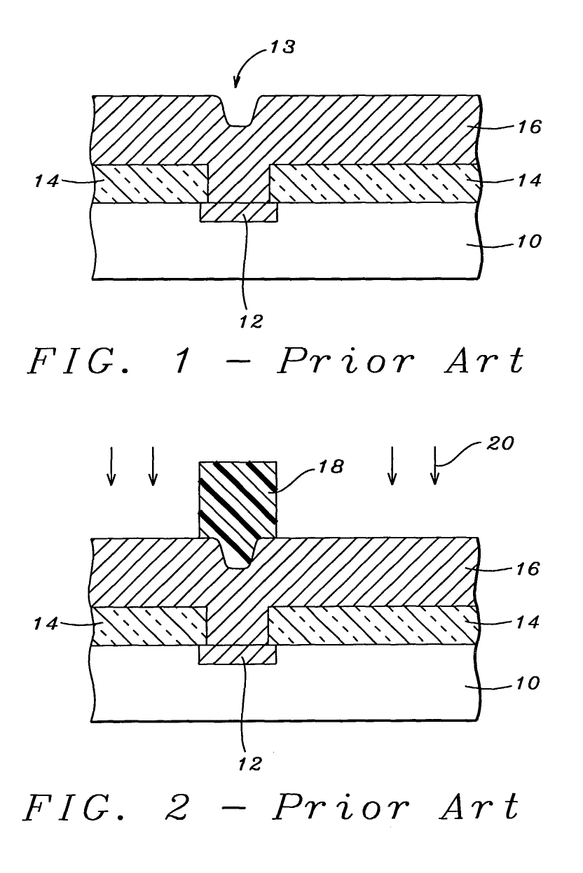

After the layer 16 of AlCu has been deposited, the layer must be patterned and etched to create an aluminum contact pad. This patterning and etching uses conventional methods of photolithography and patterning and etching by creating of a first photoresist mask 18, FIG. 2, over the surface of layer 16 of aluminum. The photoresist mask 18 is aligned with the opening 13 created through layer 14 of passivation. Using mask 18 as an etch mask, the layer 16 of aluminum is then etched, applying a plasma etch 20 and resulting in the cross section that is shown in FIG. 3. The deposited layer 16 of AlCu can be etched using Cl₂/Ar as an etchant, at a temperature between about 50 and 200 degrees C., an etchant flow rate of about 20 sccm for the Cl₂ and 1,000 sccm for the Ar, a pressure between about 50 mTorr and 10 Torr, a time of the etch between about 30 and 200 seconds.

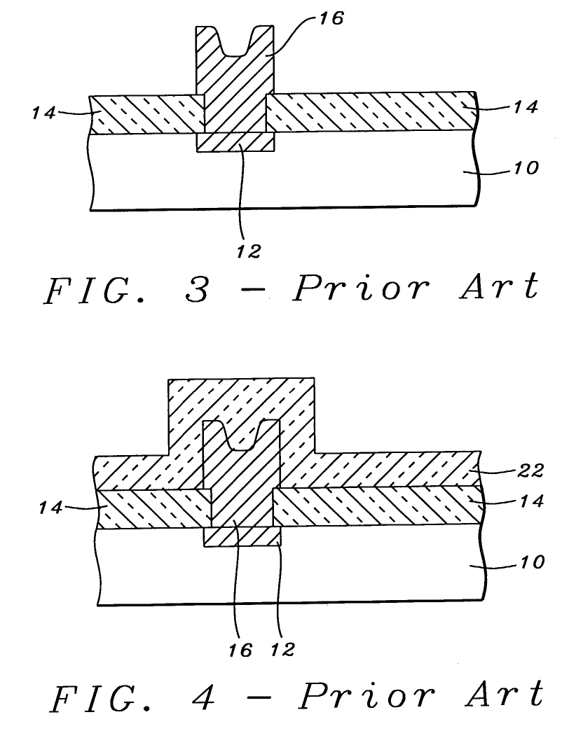

Conventional processing may, for additional protection of the created semiconductor device, select to further deposit a layer 22, FIG. 4, of passivation. This layer 22 of passivation is in turn patterned and etched, FIG. 5, using for this purpose a second photoresist mask 24 through which an opening 23 has been created. The opening 23 in this case aligns with the created aluminum pad 16 since this pad must be exposed by removing the layer 22 of passivation overlying the contact pad 16.

The etch of the layer 22 of passivation, which may also be a composite layer of passivation, results in the cross section that is shown in FIG. 6, the photoresist mask 24 has been removed in this cross section of FIG. 6.

The critical step in conventionally creating the contact pad 16 is the step of etching the layer 16, FIG. 2, of aluminum. This step applies the plasma etch 20, which leads to the introduction of hot carriers into the created contact pad 16, FIG. 3, while threshold voltage stability is negatively affected by the plasma etch 20. These effects have a negative impact on the performance of the created contact pad 16.

It is apparent from the above conventional process that a process for the creation of a bond pad whereby no plasma etch is applied results in a contact pad of improved performance. The invention provides such a process.

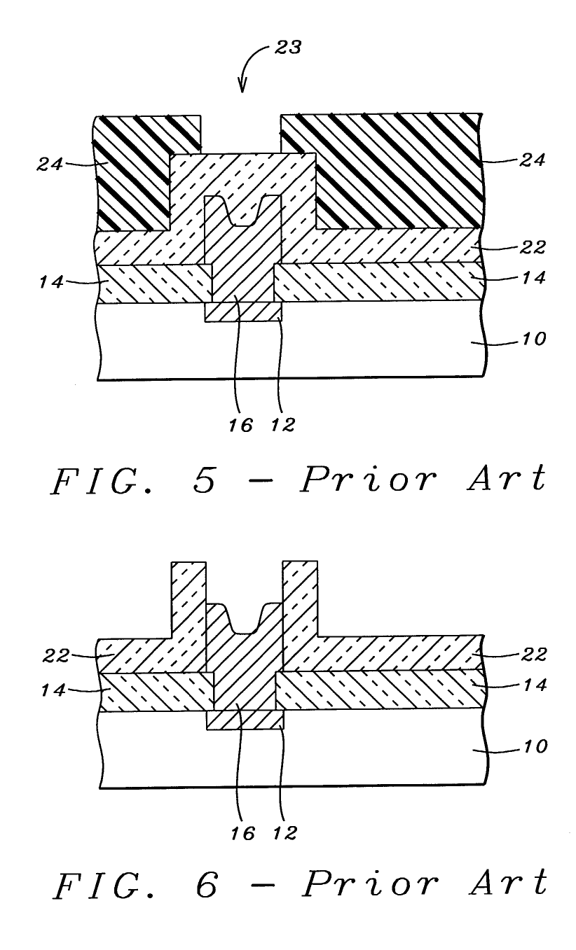

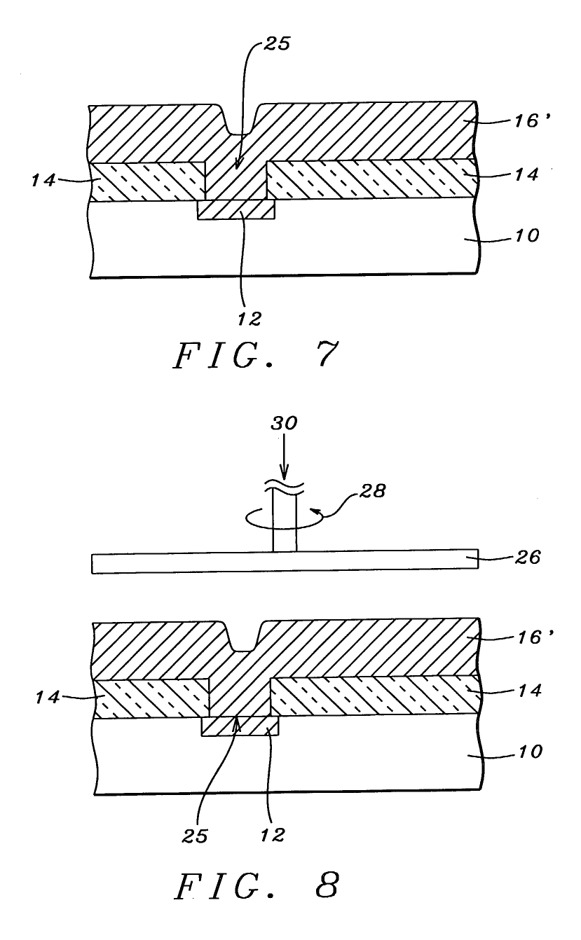

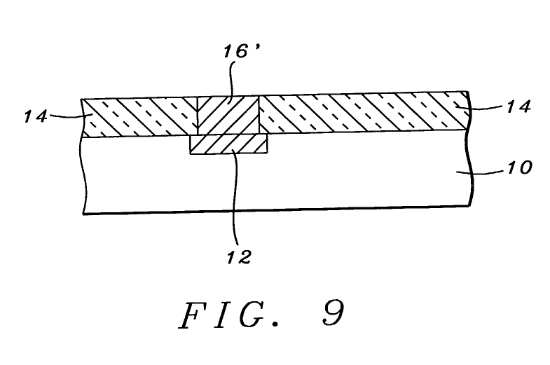

The invention starts with a semiconductor substrate 10 over which, FIG. 7, have been created a patterned and etched layer 14 of passivation over which a layer 16′ of aluminum has been deposited. Opening 25 has been filled with aluminum as a result of the deposition of the layer 16′ of aluminum. The invention then proceeds, FIG. 8, with polishing the surface of layer 16′ by applying methods of Chemical Mechanical Polishing (CMP) to the surface of layer 16′. Polishing pad 26 is for this purpose brought into contact with the surface of layer 16′, polishing of the surface of layer 16′ is provided by rotating motion 28, enhance by a downward force 30. Polishing of the surface of layer 16′ is continued to the point where essentially the surface of layer 14 has been reached, leaving in place aluminum contact pad 16′ as shown in the cross section of FIG. 9.

A number of parameters are known that determine and control the polishing operation, these parameters are:

downforce (30) applied to the polishing pad 26, typically between 0 to 15 pounds per square inch

backside pressure (not shown) applied to a rotating wafer 10, typically between 2 psi and 4 psi

slurry flow (not shown), typically between 200 sccm and 400 sccm

speed of the rotating substrate, typically between 5 rpm and 20 rpm

speed of the rotating polishing pad, typically between 5 rpm and 20 rpm, and

DIW rinse time, typically between 0 seconds and 10 seconds and 30 seconds and 60 seconds.

In comparing the cross section of FIG. 6, which shows the conventionally created contact pad 16, with the cross section of FIG. 9, which shows the contact pad created in accordance with the invention, it is clear that the contact pad 16′ of the invention has not been exposed to plasma etch and therefore does not suffer any negative impact of hot carrier penetration and migration in the created contact pad. In addition, the contact pad 16′ has significantly improved surface planarity, a planarity that is determined by characteristics of CMP polishing and that therefore can be considerably enhanced when compared with conventional methods of creating a contact pad.

In addition, the polishing of the deposited layer of aluminum can be improved by depositing a stop layer (not shown) over the surface of the layer 14 of passivation prior to the deposition of the layer 16′ of aluminum. This additional stop layer will facilitate the end-point detection of the CMP process and will therefore enhance polishing and contact pad characteristics of the created contact pad. A conventional etch stop layer can be used for this purpose by for instance reacting dichlorosilane (SiCl₂H₂) with ammonia (NH₃) in an LPCVD at a pressure between about 0.25 and 1.0 Torr, a temperature between about 650 and 750 degrees C. and at a flow rate of between about 80 and 120 sccm. The conventional etch stop layer, deposited over the surface of the layer 14 of passivation, in this application serves the dual purpose of stop layer for the CMP process and of etch stop layer in creating opening 25 through the layer 14 of passivation.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method for the creation of an aluminum contact pad, comprising steps of:
providing a substrate, at least one point of electrical contact having been provided in or over the surface of said substrate;
depositing a layer of passivation over the surface of said substrate;
creating at least one opening through said layer of passivation, said at least one opening being aligned with said at least one point of electrical contact;
depositing a layer of aluminum over the surface of said substrate, filling said at least one opening with aluminum; and
polishing the surface of said deposited layer of aluminum, removing said layer of aluminum from the surface of said layer of passivation.

2. The method of claim 1, said layer of aluminum comprising an aluminum compound.

3. The method of claim 1, additionally depositing a layer of etch stop material over the surface of said layer of passivation prior to creating at least one opening through said layer of passivation, said at least one opening being created through said layer of passivation and said layer of etch stop material, said removing said layer of aluminum from the surface of said layer of passivation being removing said layer of aluminum from the surface of said layer of etch stop material.

4. The method of claim 1, said polishing the surface of said deposited layer of aluminum comprising controlling polishing parameters of said polishing.

5. The method of claim 4, said polishing parameters being selected from the group consisting of a downforce applied to a polishing pad and backside pressure applied to a rotating wafer and slurry flow and speed of a rotating substrate and speed of a rotating polishing pad and DIW rinse time.

6. The method of claim 1, said layer of passivation comprising a compound layer of passivation.

7. A method for the creation of an aluminum contact pad, comprising steps of:
depositing a layer of aluminum over the surface of a layer of passivation provided over the surface of a substrate, filling at least one opening created through said layer of passivation; and
polishing the surface of said deposited layer of aluminum, removing said layer of aluminum from the surface of said layer of passivation.

8. The method of claim 7, said layer of aluminum comprising an aluminum compound.

9. The method of claim 7, said at least one opening created through said layer of passivation being aligned with at least one point of electrical contact provided in or over the surface of said substrate.

10. The method of claim 7, said polishing the surface of said deposited layer of aluminum comprising controlling polishing parameters of said polishing.

11. The method of claim 10, said polishing parameters being selected from the group consisting of a downforce applied to a polishing pad and backside pressure applied to a rotating wafer and slurry flow and speed of a rotating substrate and speed of a rotating polishing pad and DIW rinse time.

12. The method of claim 7, said layer of passivation comprising a compound layer of passivation.

13. A method for the creation of an aluminum contact pad, comprising steps of:
depositing a layer of aluminum over the surface of a layer of etch stop material deposited over the surface of a layer of passivation provided over the surface of a substrate, filling at least one opening created through said layer of etch stop material and said layer of passivation; and
polishing the surface of said deposited layer of aluminum, removing said layer of aluminum from the surface of said layer of etch stop material.

14. The method of claim 13, said layer of aluminum comprising an aluminum compound.

15. The method of claim 13, said at least one opening created through said layer of etch stop material and said layer of passivation being aligned with at least one point of electrical contact provided in or over the surface of said substrate.

16. The method of claim 13, said polishing the surface of said deposited layer of aluminum comprising controlling polishing parameters of said polishing.

17. The method of claim 16, said polishing parameters being selected from the group consisting of a downforce applied to a polishing pad and backside pressure applied to a rotating wafer and slurry flow and speed of a rotating substrate and speed of a rotating polishing pad and DIW rinse time.

18. The method of claim 13, said layer of passivation comprising a compound layer of passivation.
